(19) United States
(12) Patent Application Publication
(10) Pub. No.: US 2026/0155622 A1
(43) Pub. Date: Jun. 4, 2026

(54) ELEMENT MOUNTING STRUCTURE

(71) Applicant: Mitsubishi Electric Corporation, Tokyo (JP)

(72) Inventor: Nobuo YOKOMURA, Tokyo (JP)

(73) Assignee: Mitsubishi Electric Corporation, Tokyo (JP)

(21) Appl. No.: 18/717,233

(22) PCT Filed: Feb. 18, 2022
(86) PCT No.: PCT/JP2022/006540

§ 371 Date: Jun. 6, 2024

(51) Int. Cl. H10W 90/00

(52) U.S. Cl. CPC H01S 5/02315; H01S 5/0236

(57) ABSTRACT

Provided are a direction-dependent element, a substrate having a mounting surface with a plurality of grooves arranged in parallel in a region set to be biased to one side in a certain direction in an arrangement range of the direction-dependent element, and an adhesive that contains spacer particles to define an interval between objects to be bonded and bonds the direction-dependent element to the substrate. The spacer particles enter the plurality of grooves in the region, and an inclination angle is provided between the direction-dependent element and the mounting surface.

### TECHNICAL FIELD

The present application relates to an element mounting structure.

### BACKGROUND ART

When an element such as a semiconductor laser element, an optical element, or a thermal head that has direction dependence on the characteristics in the output, the detection or the like in the energy propagating through a space is used, the element may be mounted at an angle of inclination with respect to the substrate according to the direction dependence in order to achieve desired performance. In this case, an additional member such as a stainless steel plate for providing the inclination angle needs to be inserted between the substrate and the element, which complicates the configuration and the process.

In view of this, a technique has been disclosed in which adhesives containing spacer particles and having a different particle diameter each as the particle for defining an interval are used in different regions, whereby the element is mounted at an inclination angle with respect to the substrate without inserting an additional member (refer to, for example, Patent Document 1).

### PRIOR ART DOCUMENT

### Patent Document

Patent Document 1: Japanese Patent Application Laid-Open No. 2011-148241 (paragraph 0057, FIG. 4)

### SUMMARY OF INVENTION

### Problems to be Solved by Invention

However, when the adhesives containing spacer particles and having a different particle diameter each are used in different regions, the adhesives need to be handled separately, each as an adhesive having a different specification even if the base is the same. In this case, in order to accurately provide the inclination angle, it is necessary to accurately reproduce the application range in each region, which increases the possibility of variations in quality and complicates the process.

The present application discloses a technique for solving the above-described problem, and an object of the present application is to obtain an element mounting structure in which an accurate inclination angle is provided with respect to a substrate without requiring an additional member.

### Means for Solving the Problems

An element mounting structure disclosed in the present application includes a direction-dependent element having a direction dependence in at least one of characteristics of an output, detection, and manipulation in energy propagating through a space, a substrate having a mounting surface with a plurality of grooves arranged in parallel in a region set to be biased to one side in a certain direction in an arrangement range of the direction-dependent element, and an adhesive that contains spacer particles to define an interval between objects to be bonded and bonds the direction-dependent element to the substrate. The spacer particles enter the plurality of grooves in the region, and an inclination angle is provided between the direction-dependent element and the mounting surface in a plane perpendicular to the mounting surface including the certain direction.

### Advantageous Effect of Invention

According to the element mounting structure disclosed in the present application, since an inclination angle can be provided using an adhesive of a single specification containing spacer particles for defining the adhesive thickness, the element mounting structure provided with the accurate inclination angle with respect to the substrate can be obtained without requiring an additional member.

### BRIEF DESCRIPTION OF THE DRAWINGS

FIG. 1A and FIG. 1B are a plan view of a substrate portion and a cross-sectional view of a element mounting structure, showing a configuration of the element mounting structure according to Embodiment 1, respectively.

FIG. 2 is a cross-sectional view showing a configuration of the element mounting structure in a case of using an adhesive containing particles having a small particle diameter in addition to spacer particles in the element mounting structure according to Embodiment 1.

FIG. 3A to FIG. 3C are cross-sectional views of element mounting structures using substrates in each of which grooves are arranged in a different arrangement region, as the element mounting structures according to Embodiment 1.

FIG. 4A, FIG. 4B, and FIG. 4C are cross-sectional views of element mounting structures that uses substrates in each of which grooves having a different depth are formed, and a cross-sectional view of an element mounting structure that uses a substrate in which grooves having a different depth are formed depending on a region, as the element mounting structures according to Embodiment 1.

FIG. 5A, FIG. 5B, and FIG. 5C are a plan view of a substrate portion provided with grooves in a different arrangement pattern, and cross-sectional views of the element mounting structure in different cut surfaces as an element mounting structure according to a first variation of Embodiment 1, respectively.

FIG. 6A and FIG. 6B are plan views of substrate portions in each of which grooves in a further different arrangement pattern are provided as element mounting structures according to the first variation of Embodiment 1.

FIG. 7A to FIG. 7D are end views of substrate portions in each of which grooves having a different cross-sectional shape are provided as element mounting structures according to a second variation of Embodiment 1.

FIG. 8A and FIG. 8B are cross-sectional views of element mounting structures using substrates in each of which grooves are formed in a different arrangement region as element mounting structures according to Embodiment 2.

FIG. 9 is a cross-sectional view of an element mounting structure on which a prism is mounted as an application example of the element mounting structure according to Embodiment 2.

### MODE FOR CARRYING OUT INVENTION

### Embodiment 1

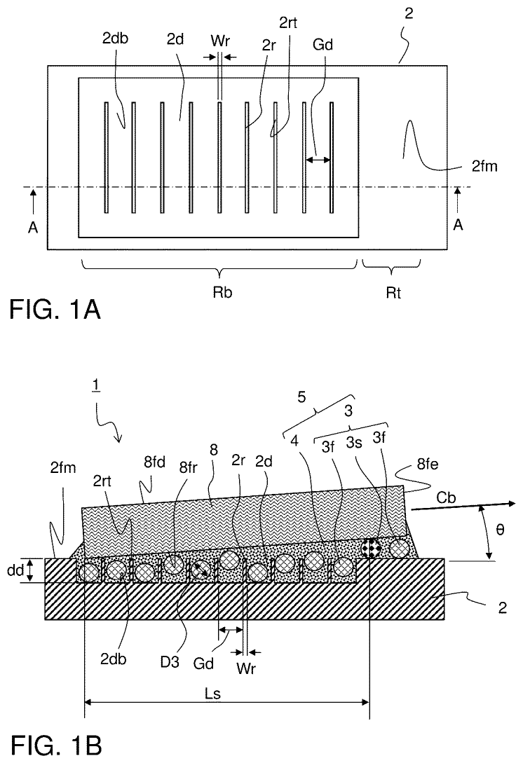

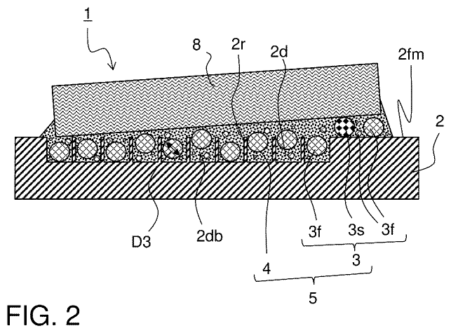

FIG. 1A and FIG. 1B are for describing a configuration of an element mounting structure according to Embodiment 1, FIG. 1A is a plan view of a substrate of the element mounting structure before mounting the element as viewed from the mounting surface side, and FIG. 1B is a cross-sectional view of the element mounting structure after mounting the element, which corresponds to a line A-A of FIG. 1A. Further, FIG. 2 is a cross-sectional view corresponding to FIG. 1B, showing a configuration of an element mounting structure using an adhesive containing particles having a small particle diameter in addition to spacer particles as a variation example.

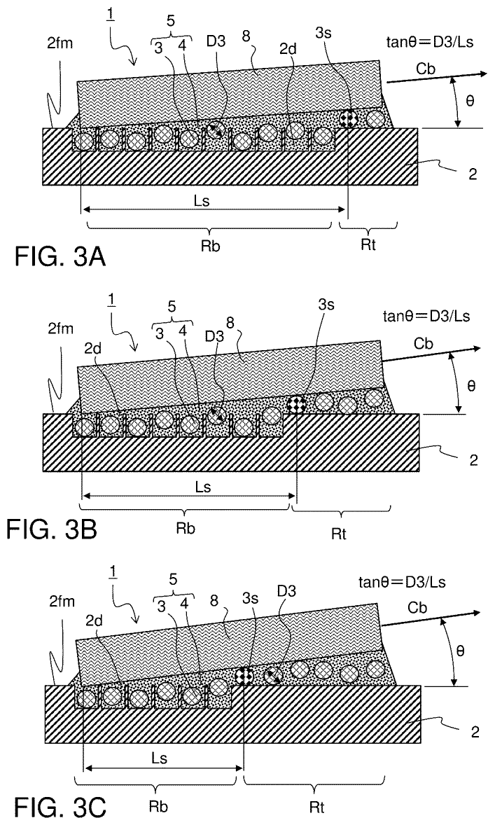

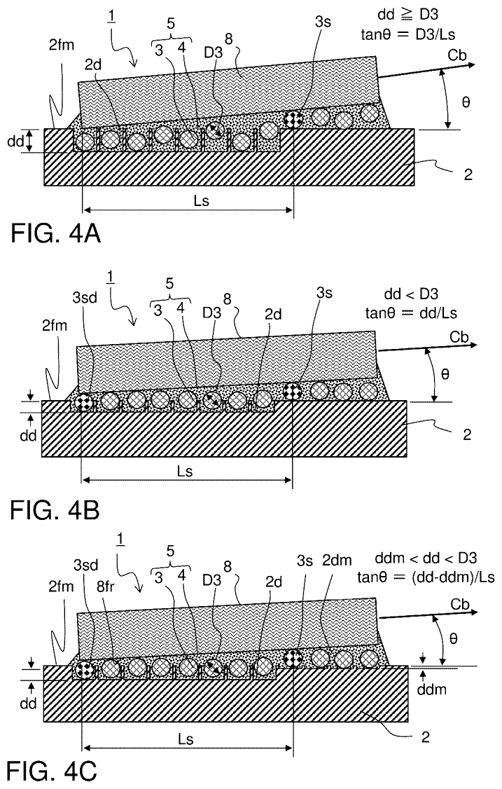

Then, FIG. 3A to FIG. 3C are cross-sectional views of the element mounting structures using substrates in each of which grooves are formed in a different arrangement region, which correspond to FIG. 1B, FIG. 4A and FIG. 4B are cross-sectional views of element mounting structures using substrates in each of which grooves are formed at a different depth, which correspond to FIG. 1B, and FIG. 4C is a cross-sectional view of an element mounting structure using a substrate in which grooves having a different depth is formed depending on a region, which correspond to FIG. 1B.

As shown in FIG. 1B, an element mounting structure 1 according to Embodiment 1 is configured such that an optical semiconductor element 8, which is a direction-dependent element, is bonded to a substrate 2 using an adhesive 5 containing spacer particles 3 and is mounted on the substrate 2 at an inclination angle θ. As the adhesive 5 interposed between a mounting surface 2fm of the substrate 2 and the optical semiconductor element 8, the adhesive 5 containing the spacer particles 3 in a base 4 for defining an interval between objects to be bonded is used.

However, the adhesive 5 to be used contains the spacer particles 3 that define the same interval across the both ends of the inclination (in the horizontal direction in the figure). That is, when the adhesive 5 is interposed between the flat surfaces, the adhesive 5 that has the same specification and uses the spacer particles 3 in the same particle diameter D3 as the particle diameter D3 for defining the interval between flat surfaces is used in the entire adhesive region.

In contrast, the mounting surface 2fm of the substrate 2 for mounting the optical semiconductor element 8 is flat in a region Rt on the right side of the figure, but in a region Rb on the left side of the figure, grooves 2d having a groove width Gd larger than the particle diameter D3 of the spacer particles 3 are arranged in parallel in a pattern as shown in FIG. 1A.

The groove width Gd of the grooves 2d to be formed in the substrate 2 is set, for example, to be larger than the particle diameter D3 as a width that allows the spacer particles 3 to enter the grooves 2d. A ridge portion 2r between the adjacent grooves 2d is formed in a shape such that the spacer particles 3 do not stably stay on top portion 2rt, or it has a ridge width Wr smaller than the particle diameter D3.

Therefore, in the region Rb, the spacer particles 3 enter the grooves 2d. Further, the depth of the grooves 2d (groove depth dd) is deeper than the particle diameter D3. As a result, the spacer particles 3 in the region Rb are in a floating state in the base 4 between the optical semiconductor element 8 and a bottom 2db of the grooves 2d and are free particles 3f that do not contribute to the definition of the interval between a bonding surface 8fr of the optical semiconductor element 8 and the substrate 2. That is, in the region Rb, there is no structure for holding the mounting surface 2fm and the bonding surface 8fr of the optical semiconductor element 8 with an interval therebetween.

On the other hand, in the region Rt, the spacer particles 3 are positioned on the flat mounting surface 2fm, and can have a function of forming an interval corresponding to the particle diameter D3 between the mounting surface 2fm and the bonding surface 8fr of the optical semiconductor element 8. That is, a difference in the bonding thickness occurs between both ends in the horizontal direction of the figure, and the bonding surface 8fr is to be inclined with respect to the mounting surface 2fm. Note that, among the spacer particles 3 in the region Rt, at their positions away from the region Rb, the interval is larger than the particle diameter D3, and thus the spacer particles 3 at their positions closest to the region Rb function as contributing particles 3s that contribute to the definition of the thickness.

As shown in Expression (1), the inclination angle θ is determined by a distance Ls from an end of the bonding surface 8fr on the region Rb side up to the contact with the contributing particles 3s and the particle diameter D3. The distance Ls can be adjusted with the range of the region Rb, and thus the inclination angle θ can be provided with good reproducibility. However, care should be taken because an excessively large inclination angle θ is presumed to cause difficulty in fixing the optical semiconductor element 8.

$$tan θ = D 3 / Ls \qquad ( 1 )$$

For example, when the optical semiconductor element 8 is a laser semiconductor element, a beam center Cb of the laser light output from an end face 8fe can be inclined at the inclination angle θ with respect to the mounting surface 2fm of the substrate 2. Alternatively, when the optical semiconductor element 8 is a photodiode chip that reflects the laser light on a detection surface 8fd and also detects the laser intensity, the detection surface 8fd that also serves as a reflection surface can be inclined at the inclination angle θ with respect to the mounting surface 2fm.

The details of each of members and a process for forming the structure in which the inclination angle θ can be easily set will be described below. The adhesive 5 to be used for bonding the substrate 2 and the direction-dependent element such as the optical semiconductor element 8 functions as a bonding material, and also is utilized for controlling the interval between objects to be bonded by containing the spacer particles 3. The conditions required for the spacer particles 3 are not particularly limited with respect to the quality of the material, but the shape is important.

First, about the size of the spacer particles 3, the size (thickness) in the normal direction of the mounting surface 2fm in the state where the adhesive 5 is applied to the substrate 2 is important, and the maximum value (particle diameter D3) is a factor for determining the interval. It is necessary that the spacer particles 3 having the same size as a spacer particle having the maximum size (thickness) exist in a large amount in the adhesive 5, but coarse particles exceeding the maximum value cannot be used.

On the other hand, the particles contained in the adhesive 5 are not necessarily only the spacer particles 3 (single size) that define the interval as shown in FIG. 1B, and as shown in the variation example of FIG. 2, particles of any size may be contained as long as the size is equal to or smaller than the particle diameter D3. However, the particle diameter is required to be a size of a particle that does not stay on a top portion 2rt and does not affect the interval, or a particle diameter that can set the inclination angle θ depending on the particle diameter when the particle stays on the top portion 2rt. The shape of the particles is not particularly limited as long as the above conditions are satisfied, but spherical particles are most suitable for practical use.

With the grooves 2d provided in the region Rb on one end side along the plane for the formation of the inclination angle θ in the mounting surface 2fm of the substrate 2, an example of limiting the interval defining function of the spacer particles 3 in the region Rb has been shown. Here, as a means for limiting the interval defining function, for example, it is also considered to recess the entire region Rb. In this case, since the optical semiconductor element 8 sinks to the bottom surface of the recess, it is possible to provide the inclination without the spacer particles 3, but the bending rigidity of the substrate 2 is reduced.

Therefore, there is a concern that the reproducibility of the inclination angle θ may be reduced due to the deformation of the substrate 2 or the yield may be reduced due to the breakage of the substrate 2. It is conceivable to increase the bending rigidity by increasing the thickness of the substrate 2, but this would make it bulky as a mounting structure, making miniaturization difficult and impractical.

On the other hand, when the grooves 2d are arranged in parallel such that the ridges 2r and the grooves 2d are alternately arranged as in the present application, without impairing the bending rigidity, a desired inclination angle θ can be provided by the particle diameter D3 of the spacer particles 3 and the distance Ls that can be controlled by setting an arrangement range (region Rb) of the grooves 2d.

For example, in FIG. 3A to FIG. 3C, end portions (left end portions in the figures) of the region Rb on the side far from the region Rt in the arrangement range of the grooves 2d are the same, but the end portions (right end portions in the figures) closer to the region Rt are shifted to the left side and the arrangement range becomes narrower as the figure proceeds from FIG. 3A to FIG. 3C. Since the contributing particles 3s are located in the region Rt at the boundary between the region Rt and the region Rb as described above, the distances Ls is shorter and the inclination angle θ is larger as the right end portion of the region Rb moves to the left.

Further, even when the same distance Ls (the range of the region Rb) and the same particle diameter D3 are used, the inclination angle θ can be adjusted by setting the groove depth dd. For example, as shown in FIG. 4A, the groove depth dd (≥D3) at which the spacer particles 3 completely sink into the grooves 2d is considered as a basic depth, but this is not a limitation.

As shown in FIG. 4B, when the grooves 2d are formed with the groove depth dd (<D3) smaller than the particle diameter D3, the spacer particles 3 in the grooves 2d do not completely sink in the grooves 2d, and part of the spacer particles 3 protrudes to a position higher than the mounting surface 2fm. Among the spacer particles 3 protruding from the mounting surface 2fm in the region Rb, the particles in contact with the bonding surface 8fr at the position farthest from the region Rt function as second contributing particles 3sd that define the interval between the bonding surface 8fr and the mounting surface 2fm, the interval having a value obtained by subtracting the groove depth dd from the particle diameter D3. That is, the inclination angle θ can be set on the basis of Expression (2).

$$tan θ = dd / Ls \qquad ( 2 )$$

Further, as shown in FIG. 4C, even when a groove 2dm having a groove depth ddm shallower than the grooves 2d is provided in the region Rt (ddm<dd<D3), the inclination angle θ can be set on the basis of Formula (3). That is, the inclination angle θ can be set even by combining grooves having multiple types in depth.

$$tan θ = ( dd - ddm ) / Ls \qquad ( 3 )$$

As shown in FIG. 4A and FIG. 4C, when some of the spacer particles 3 entering into the grooves are made to protrude from the mounting surface 2fm, for example, by half or more of the particle, the groove width Gd are not necessarily set to be wider than the particle diameter D3. The width may be set as appropriate depending on the amount of protrusion or the depth of the entry.

### First Variation

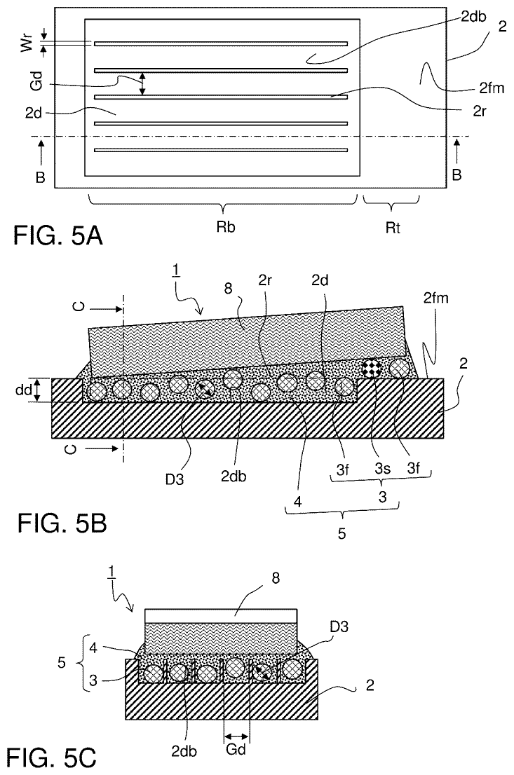

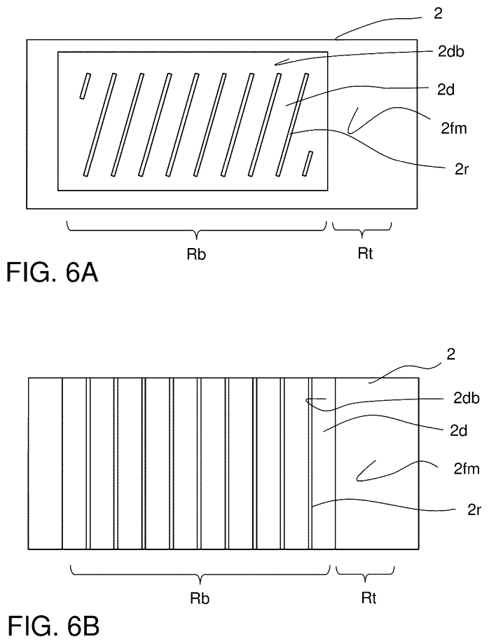

Next, as a first variation, various arrangement patterns of the grooves for limiting the interval defining function of the spacer particles will be exemplified. FIG. 5A is a plan view of a substrate portion of an element mounting structure corresponding to FIG. 1A according to the first variation, FIG. 5B is a cross-sectional view corresponding to a line B-B of FIG. 5A, and FIG. 5C is a cross-sectional view corresponding to a line C-C of FIG. 5B. Further, FIG. 6A and FIG. 6B are plan views of substrate portions corresponding to FIG. 5A, in each of which grooves are provided in a further different arrangement pattern.

As the arrangement pattern of the grooves 2d, the arrangement pattern in which the grooves 2d extend in the direction orthogonal to the direction in which the optical semiconductor element 8 is inclined (the direction along the plane in which the inclination angle θ is provided) on the mounting surface 2fm has been described in FIG. 1A and FIG. 1B, but the arrangement pattern is not limited thereto. For example, as shown in FIG. 5A to FIG. 5C, the arrangement pattern may be such that the grooves 2d extend parallel with respect to the direction in which the optical semiconductor element 8 is inclined.

Further, as shown in FIG. 6A, the grooves 2d may extend obliquely with respect to the direction in which the optical semiconductor element 8 is inclined. Here, when terminal end portions of the grooves 2d do not reach any end of the mounting surface 2fm, the terminal ends are preferably arranged so as not to form a dead end. Specifically, with respect to the terminal end portions in the extending direction of the grooves 2d, it is preferable to provide a space that can allow the adhesive 5 containing the spacer particles 3 to flow in from the adjacent grooves 2d by connecting the adjacent grooves 2d with each other for the dead end not to occur. For example, if there is no space other than the mounting surface 2fm side for an excess adhesive to escape in a certain groove 2d, it may be possible that the spacer particles 3 are stuck and stacked in the groove 2d and may be higher than the mounting surface 2fm, thereby forming an extra interval.

The above-described arrangement pattern corresponds basically to a shape in which the adhesive 5 is retained within the mounting surface 2fm of the substrate 2, but as shown in FIG. 6B, the grooves 2d may be extended so as to be opened to the end portion of the substrate 2, and thus the excess adhesive 5 may be discharged to the outside of the substrate. However, care must be taken so that the discharged adhesive 5 does not cause a problem.

The positional relationship between the optical semiconductor element 8 and the arrangement range of the grooves 2d at the time of mounting is freely selected in a range as long as the inclination angle θ does not deviate from an allowable value in the region Rb in which the grooves 2d are arranged for narrowing the interval between the optical semiconductor element 8 and the substrate 2. However, the positional relationship affects more than just the setting of the inclination angle θ, and it is necessary to consider the influence on the bonding strength and on the sticking of the adhesive 5 to a portion other than the bonding surface 8fr of the optical semiconductor element 8.

### Second Variation

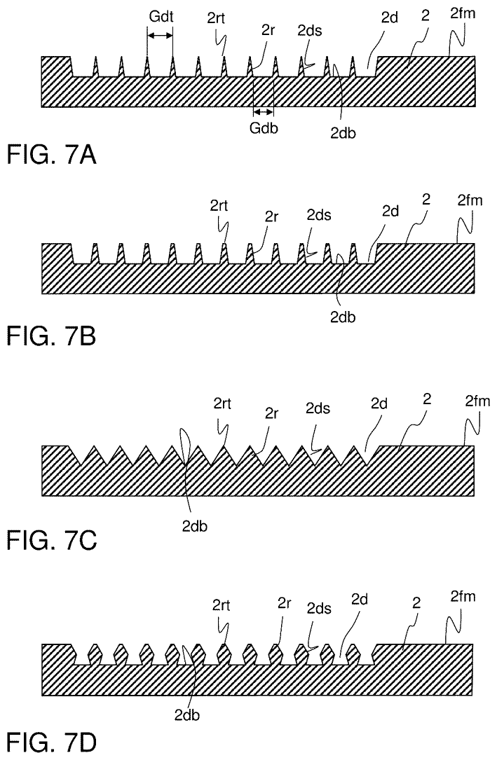

Next, as a second variation, various forms about the cross-sectional shape perpendicular to the extending direction of the grooves that limit the interval defining function of the spacer particles will be exemplified. FIG. 7A to FIG. 7D are end views of substrates in each of which grooves having a different cross-sectional shape are provided as an element mounting structure according to the second variation, the end views corresponding to a cut surface taken along a line A-A in FIG. 1A, for example.

In the cross-sectional shape perpendicular to the extending direction of the grooves 2d, as a basic condition, the groove width Gd that allows the spacer particles 3 to enter is required, and the ridge portion 2r to be formed between the adjacent grooves 2d requires a size (ridge width Wr) and a shape that do not allow the spacer particles 3 to stay on the top portion 2rt. With the above in mind, in the above-described example, the grooves 2d having a simple rectangular cross-sectional shape represented in FIG. 1B is exemplified.

The grooves 2d in a rectangular shape are simple and therefore are good in workability, and are in a shape that allows a large amount of the adhesive 5 containing the spacer particles 3 to be taken in. On the other hand, the ridge portion 2r that is required not to retain the spacer particles 3 is not strong, and the bottom 2db is not optimal from the viewpoint of the fluidity of the adhesive 5. If the ridge portion 2r is reinforced in its strength in a simple manner, a shape in which the ridge width Wr is widened is considered, but since the possibility that the spacer particles 3 stay on the top portion 2rt increases, sufficient verification is required.

Therefore, as shown in FIG. 7A, by sharpening the top portion 2rt, even when the ridge width Wr is increased until a necessary strength is obtained, the spacer particles 3 can be prevented from staying on the top portion 2rt. Although the top portion 2rt has a shape effective for preventing the problem of the stay of the spacer particles 3 on the top portion 2rt, sufficient care must be taken not to damage each other when it is brought into contact with the optical semiconductor element 8. Therefore, as shown in FIG. 7B, a side face 2ds is inclined, but the top portion 2rt may be made wider than that in FIG. 7A such that the tip thereof is made less sharp.

In these cases, since the side face 2ds is inclined, the fluidity of the adhesive 5 in the grooves 2d is considered to be improved, and the groove width Gd changes depending on the depth such that a groove width Gdb on the side of the bottom 2db is smaller than the groove width Gdt on the side of the top portion 2rt. Therefore, the spacer particles 3 cannot always come into contact with the bottom 2db, and the inclination angle θ described in Expressions (1) to (3) needs to be corrected on the basis of the selection for the upper limit of the particle diameter D3 required for the contact, or the sinking depth of the spacer particles 3 depending on the contact state.

Further, as shown in FIG. 7C, the flat portion of the bottom 2db may be eliminated. The shape is such that the strength of the ridge portion 2r is greatly enhanced as compared with that in the rectangular shape. However, the change in the groove width Gd toward the bottom 2db is large, and the spacer particles 3 cannot make contact with the bottom 2db. Therefore, it is necessary to calculate the sinking height of the spacer particles 3 depending on the relationship between the groove shape and the particle diameter D3, rather than the cases shown in FIG. 7A and FIG. 7B.

Alternatively, as shown in FIG. 7D, the side face 2ds is inclined such that the groove width Gd is increased as a distance from the bottom 2db is increased on the side of the bottom 2db to form an anchor, thereby improving the bonding strength. While forming such an anchor is effective in cases where strong bonding is required, it is disadvantageous in that the upper limit of the permissible particle diameter D3 is reduced and the time and effort required for groove processing is increased.

That is, any cross-sectional shape has both advantage and disadvantage, and it is desirable to provide the grooves 2d with an appropriate cross-sectional shape in accordance with the substrate specification and the requirement specification.

On the premise of the above-described configuration, a process of mounting a direction-dependent element such as the optical semiconductor element 8 on the substrate 2 using a die bonding apparatus as a mounting apparatus will be described. First, the substrate 2 is transferred to a die bonding stage by the die bonding apparatus, and the substrate 2 is aligned. Next, the adhesive 5 is applied onto the substrate 2 by a coating machine such as a dispenser. The application position and the application amount of the adhesive 5 are set in consideration of the mounting position of a direction-dependent element and the fluidity of the adhesive 5 at the time of mounting.

After the adhesive is applied, the direction-dependent element is transferred to a die bonding position and a load is applied. With respect to the load at the time of die bonding of the element, it is desirable to incorporate a mechanism for averaging the load into the transfer mechanism of the direction-dependent element or the die bonding stage (a flexible joint mechanism or the like in the shaft portion in the case of the transfer mechanism, and a cushion mechanism or the like in the case of the die bonding stage). This makes it possible to push the direction-dependent element into contact with the spacer particles 3 or the mounting surface 2fm, at both ends of the inclination, and thus to obtain the inclination angle θ as designed. In this state, curing treatment such as UV irradiation, heating, or holding for a certain period of time is performed depending on the adhesive 5, whereby the element mounting structure 1 in which the direction-dependent element is mounted on the substrate 2 at the inclination angle θ can be obtained.

As described above, by mounting the direction-dependent element using the substrate 2 in which the grooves 2d are arranged in parallel for the spacer particles 3 to enter in the region Rb on one end side in the direction in which the inclination is provided, it is possible to perform the mounting in which the inclination angle θ is provided by using only the adhesive 5 having one type of specification. That is, no additional member is required, and the adhesive 5 does not need to be applied in multiple times, so that the number of steps and the time are expected to be reduced.

Further, since the range in which the grooves 2d are arranged is constant, the position in the portion where the spacer particles 3 do not contribute to the interval, that is, in the portion where the interval relative to the mounting surface 2fm is narrow, and the position in the portion where the spacer particles 3 contribute to the interval, that is, in the portion where the interval is wide, are fixed to be constant. Therefore, the variation of the mounting in the manufacturing is reduced, and the variation of the quality in the manufacturing is reduced, so that the yield is improved. In addition, by time savings and reduction in high labor processes, an effect of reducing the increase in operating cost is brought about.

### Embodiment 2

In Embodiment 1, the examples have been described in which the application range of the adhesive is set such that the adhesive is interposed between the substrate and the direction-dependent element without interruption from the region where the grooves are arranged in parallel to the region where the grooves are not arranged. In Embodiment 2, an example in which the adhesive is intermittently applied between the region where the grooves are arranged in parallel and the region where the grooves are not arranged will be described.

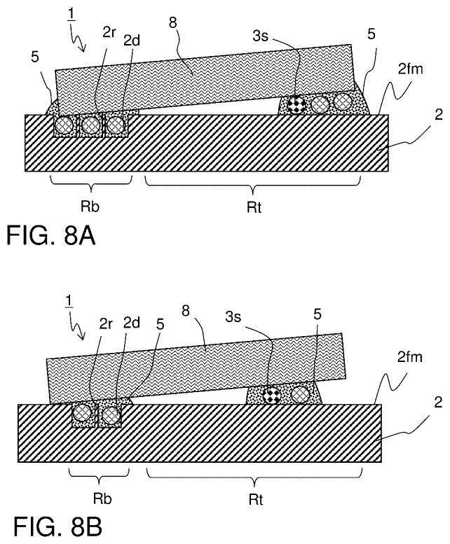

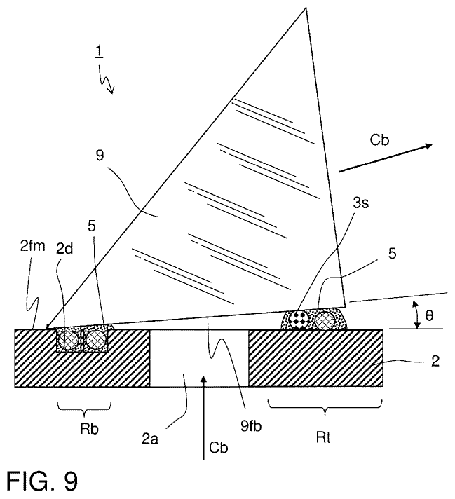

FIG. 8A, FIG. 8B, and FIG. 9 are for describing configurations of element mounting structures according to Embodiment 2, and FIG. 8A is a cross-sectional view corresponding to FIG. 1B of Embodiment 1, showing the configuration of an element mounting structure, and FIG. 8B is a cross-sectional view of an element mounting structure using a substrate in which the grooves are formed in an arrangement range different from that of FIG. 8A. FIG. 9 is a cross-sectional view of an element mounting structure in which a prism is mounted as a direction-dependent element as an application example of the element mounting structure according to Embodiment 2. Note that the same portions as those in Embodiment 1 are denoted by the same reference numerals, and the description thereof will be omitted.

In the element mounting structures 1 according to Embodiment 2, as shown in FIG. 8A and FIG. 8B, the application range of the adhesive 5 is set to be separated into a region Rb where the grooves 2d are arranged in parallel and the region Rt where the flat surface as the mounting surface 2fm spreads. In FIG. 8A, an example will be shown in which the application range is set so as to cover an edge of the element in each region. Further, in FIG. 8B, an example will be shown in which the application range is set so as not to cover the edge of the element

The application range in the depth direction of the figure may extend in a line shape, or may be interrupted at an intermediate portion, for example, the vicinity of the four corners may be set as the application range, and may be appropriately set on the basis of the bonding strength, the position where the application is possible, and the like in the specification. In any case, the inclination angle θ can be set accurately with good reproducibility, as in the case where the adhesive 5 is applied continuously over the region Rb and the region Rt as described in Embodiment 1.

As an effective application example of intermittently setting the application range, as shown in FIG. 9, a case is considered in which an optical element such as a prism 9 is mounted as the direction-dependent element for manipulating light by refraction, reflection, or the like. In this case, the substrate 2 is provided with an aperture 2a in a region corresponding to an incident surface 9fb of the prism 9. Then, the region Rb where the grooves 2d are arranged in parallel and the region Rt having a continuous flat surface where the spacer particles 3 function as the contributing particles 3s are set so that the incident surface 9fb should be inclined at the inclination angle θ with respect to the mounting surface 2fm.

The adhesive 5 is separated into ranges set separately in the region Rb and the region Rt, and is intermittently applied except for the aperture 2a. With this configuration, for example, a laser beam whose beam center Cb is directed directly upward from below the substrate 2 in the figure through the aperture 2a can be manipulated to be incident on the incident surface 9fb and to emit at a desired angle (beam center Cb) determined by the set inclination angle θ.

That is, by intermittently applying the adhesive 5, the laser beam can be passed through in the thickness direction of the substrate 2, and the laser beam can be taken in from the rear side of the substrate 2. In addition, possible applications are considered in such a case of a direction-dependent element in which the adhesive 5 should not be spread to the vicinity of the center in the bonded portion, or a case where the adhesive 5 is difficult to be effective when the adhesive area spreads. Further, the amount of adhesive to be used can be reduced, which is effective in reducing the cost of the member.

Furthermore, although various exemplary embodiments and examples are described in the present application, various features, aspects, and functions described in one or more embodiments are not inherent in an application of the contents disclosed in a particular embodiment, and can be applicable alone or in their various combinations to each embodiment. Accordingly, countless variations that are not illustrated are envisaged within the scope of the art disclosed in the specification of the present application. For example, the case where at least one component is modified, added or omitted, and the case where at least one component is extracted and combined with a component disclosed in another embodiment are included.

For example, the present application assumes a situation in which substantially the entire surface of the mounting surface 2fm of the substrate 2 is the installation range of the direction-dependent element, but this is not a limitation. A limited range of the mounting surface 2fm may be set as the installation range, and the grooves 2d may be arranged in parallel in the region Rb biased in a certain direction in the installation range. In addition, when there are a plurality of installation ranges, the specifications such as the parallel arrangement range of the grooves 2d and the groove depth dd should be set according to the inclination direction and the inclination angle θ to be set in each installation range.

Further, although the elements for handling light such as laser light are exemplified as the direction-dependent elements, this is not a limitation. Any element may be used as long as it has a direction dependence in the characteristics of an output and detection or of manipulation such as converging, diverging, course changing or separating, in energy such as radiation or heat propagating through space.

As described above, the element mounting structure 1 of the present application includes a direction-dependent element (optical semiconductor element 8, prism 9) having a direction dependence in at least one of characteristics of an output, detection, and manipulation in energy propagating through a space, the substrate 2 having the mounting surface 2fm with the plurality of grooves 2d arranged in parallel in the region Rb set to be biased to one side (left side in FIG. 1A) in the certain direction (for example, horizontal direction in FIG. 1A) in the arrangement range of the direction-dependent element, and the adhesive 5 that contains the spacer particles 3 to define the interval between the objects to be bonded and bonds the direction-dependent element to the substrate 2. The spacer particles 3 enter the plurality of grooves 2d in the region Rb, and the inclination angle θ is provided between the direction-dependent element and the mounting surface 2fm in a plane perpendicular to the mounting surface 2fm including the certain direction. Therefore, the element mounting structure 1 provided with the accurate inclination angle θ with respect to the substrate 2 can be obtained using the adhesive 5 of a single specification without requiring an additional member.

At this time, when a spacing (ridge width Wr) between the plurality of grooves 2d is set to be narrower than the particle diameter D3 of the spacer particles 3, the spacer particles 3 can be smoothly entered into the grooves 2d without staying on the ridge 2r.

When the terminal ends of the plurality of grooves 2d are opened at the side end of the substrate 2 or are connected to the adjacent grooves 2d, the excess adhesive 5 can be prevented from overflowing onto the mounting surface 2fm.

When the plurality of grooves 2d have a different depth along the certain direction, the inclination angle θ can be changed without changing the particle diameter D3.

When the adhesive 5 is configured to be interposed between the direction-dependent element and the mounting surface 2fm so as to be separated into the portion including the region Rb and the portion on the other side in the certain direction (for example, the region Rt), for example, laser light can be irradiated from the rear side toward the optical device through the aperture 2a provided in the substrate 2 to perform desired optical processing.

When a semiconductor laser element (optical semiconductor element 8) is used as the direction-dependent element, a semiconductor laser device capable of emitting laser light at a desired angle can be obtained without requiring an additional member.

When an optical device (prism 9) is used as the direction-dependent element, an optical device capable of manipulating the state of received light into a desired state without requiring an additional member can be obtained.

### DESCRIPTION OF REFERENCE NUMERALS AND SIGNS

1: element mounting structure, 2: substrate, 2d: groove, 2fm: mounting surface, 3: spacer particles, 4: base, 5: adhesive, 8: optical semiconductor element (direction-dependent element), 8fr: bonding surface, 9: prism (direction-dependent element), 9fb: incident surface (bonding surface), D3: particle diameter, dd: groove depth, Gd: groove width, Rb: region (first region), Wr: ridge width, θ: inclination angle

1. An element mounting structure comprising:
a direction-dependent element having direction dependence in at least one of characteristics of an output, detection, and manipulation in energy propagating through a space;
a substrate having a mounting surface with a plurality of grooves arranged in parallel in a region set to be biased to one side in a certain direction in an arrangement range of the direction-dependent element; and
an adhesive that contains spacer particles to define an interval between objects to be bonded and bonds the direction-dependent element to the substrate, wherein
the spacer particles enter the plurality of grooves in the region, and an inclination angle is provided between the direction-dependent element and the mounting surface in a plane perpendicular to the mounting surface including the certain direction.

2. The element mounting structure according to claim 1, wherein a spacing between the plurality of grooves is smaller than a particle diameter of the spacer particles.

3. The element mounting structure according to claim 1, wherein terminal ends of the plurality of grooves are opened at a side end of the substrate or are connected to adjacent grooves.

4-7. (canceled)

8. The element mounting structure according to claim 2, wherein terminal ends of the plurality of grooves are opened at a side end of the substrate or are connected to adjacent grooves.

9. The element mounting structure according to claim 1, wherein the plurality of grooves have a different depth along the certain direction.

10. The element mounting structure according to claim 2, wherein the plurality of grooves have a different depth along the certain direction.

11. The element mounting structure according to claim 3, wherein the plurality of grooves have a different depth along the certain direction.

12. The element mounting structure according to claim 8, wherein the plurality of grooves have a different depth along the certain direction.

13. The element mounting structure according to claim 1, wherein the adhesive is interposed between the direction-dependent element and the mounting surface so as to be separated into a portion including the region and a portion on the other side in the certain direction.

14. The element mounting structure according to claim 2, wherein the adhesive is interposed between the direction-dependent element and the mounting surface so as to be separated into a portion including the region and a portion on the other side in the certain direction.

15. The element mounting structure according to claim 3, wherein the adhesive is interposed between the direction-dependent element and the mounting surface so as to be separated into a portion including the region and a portion on the other side in the certain direction.

16. The element mounting structure according to claim 8, wherein the adhesive is interposed between the direction-dependent element and the mounting surface so as to be separated into a portion including the region and a portion on the other side in the certain direction.

17. The element mounting structure according to claim 1, wherein a semiconductor laser element is used as the direction-dependent element.

18. The element mounting structure according to claim 2, wherein a semiconductor laser element is used as the direction-dependent element.

19. The element mounting structure according to claim 3, wherein a semiconductor laser element is used as the direction-dependent element.

20. The element mounting structure according to claim 8, wherein a semiconductor laser element is used as the direction-dependent element.

21. The element mounting structure according to claim 1, wherein an optical device is used as the direction-dependent element.

22. The element mounting structure according to claim 2, wherein an optical device is used as the direction-dependent element.

23. The element mounting structure according to claim 3, wherein an optical device is used as the direction-dependent element.

24. The element mounting structure according to claim 8, wherein an optical device is used as the direction-dependent element.
